(19) United States
(12) Patent Application Publication
(10) Pub. No.: US 2025/0138114 A1
(43) Pub. Date: May 1, 2025

(54) MEASURING ASSEMBLIES AND METHOD FOR DETERMINING A MAGNETIC GRADIENT FORCE AND THE DISTRIBUTION THEREOF

(71) Applicant: Helmholtz-Zentrum Dresden-Rossendorf e.V., Dresden (DE)

(72) Inventors: Zhe Lei, Dresden (DE); Barbara Fritzsche, Dresden (DE); Kerstin Eckert, Dresden (DE)

(21) Appl. No.: 18/705,867

(22) PCT Filed: Nov. 4, 2022
(86) PCT No.: PCT/EP2022/080804

§ 371 Date: Apr. 29, 2024

(30) Foreign Application Priority Data
Nov. 8, 2021 (DE) 102021129034.1

(51) Int. Cl. G01R 33/10; G01R 33/022

(52) U.S. Cl. CPC G01R 33/10; G01R 33/022

(57) ABSTRACT

The invention relates to a measuring assembly (10) for determining a distribution of the magnetic gradient force, comprising a probe body (20) in which a hollow space (25) is formed. There is a probe suspension (30) in the hollow space (25), which contains a fluid (31) and at least one diamagnetic particle (35). A measuring device (40) is designed to determine a distance d of the diamagnetic particle/s (35) relative to a reference plane (29) on the probe body (20). A probe positioning unit (60) is designed to determine a geometric location of the hollow space (25) and/or the at least one particle (35) relative to a stationary reference location (69) outside the probe body (20).

### TECHNICAL FIELD

The present application relates to a measuring assembly for determining the magnetic gradient force and, in particular, for determining the spatial distribution of the magnetic gradient force in a magnetic field. In addition, the application relates to a method for determining the magnetic gradient force, in particular, for determining the distribution of the magnetic gradient force in a magnetic field.

### BACKGROUND

In an inhomogeneous magnetic field, a force is exerted on a diamagnetic body in the direction of decreasing magnetic field strength. This so-called magnetic gradient force fₘ (also called “Kelvin force”) is proportional to the magnetic flux density [symbol] and to the gradient of the magnetic flux density ∇ [symbol] .

Numerous methods for manipulating, sorting and analyzing diamagnetic particles and bodies that contain diamagnetic materials, e.g., organic cells, are based on the magnetic gradient force. For example, approaches for environmentally friendly processes for the magnetic separation of rare earth ions from liquids use the magnetic gradient force.

The magnetic gradient force at a location within a magnetic field can be determined indirectly by measuring the magnetic field strength at points as close to one another as possible, for example, by means of Hall probes. To determine the magnetic gradient force based on measured field strengths, a locally linearly stratified contribution [symbol] ·∇ [symbol] is assumed, i.e., a locally homogeneous magnetic field change. Especially for applications in the field of microfluidics and in the biological context, the assumption of a locally homogeneous magnetic field change often does not apply. The possible spatial resolution of such measuring methods is therefore limited.

### SUMMARY

The present application is based on the object of determining the magnetic gradient force with high accuracy and, in particular, a spatial distribution of the magnetic gradient force with high spatial resolution.

This object is achieved with the measuring assemblies and with the methods according to the independent claims. Advantageous embodiments emerge from the dependent claims.

The following figures show embodiments of the measuring assemblies according to the invention or the method according to the invention. The elements and structures shown in the figures are not necessarily depicted true to scale to one another. Identical reference numerals refer to identical or corresponding elements and structures.

### BRIEF DESCRIPTION OF THE DRAWINGS

FIG. 1 shows a schematic block diagram of part of a measuring assembly for determining the distribution of the magnetic gradient force according to one embodiment with a probe suspension that contains a liquid with a paramagnetic phase and a diamagnetic particle.

FIG. 2 shows a schematic block diagram of a measuring assembly for determining the distribution of the magnetic gradient force with a probe positioning unit according to one embodiment.

FIG. 3 shows a schematic cross section of a probe body of a measuring assembly for determining the distribution of the magnetic gradient force according to one embodiment with a probe suspension that contains two liquid phases and a diamagnetic particle.

FIG. 4 shows a schematic block diagram of a measuring assembly for determining the distribution of the magnetic gradient force including a schematic cross section of a probe body according to one embodiment with an optical measuring device.

FIG. 5 shows a schematic block diagram of a measuring assembly for determining the distribution of the magnetic gradient force including a schematic cross section of a probe body according to one embodiment with a measuring device for impedance measurement.

FIG. 6 shows a schematic block diagram of a measuring assembly for determining the distribution of the magnetic gradient force including a schematic cross section of a probe body according to another embodiment with a measuring device with three electrodes for impedance measurement.

FIG. 7 shows a schematic block diagram of a measuring assembly for determining the distribution of the magnetic gradient force including a schematic cross section of a probe body according to one embodiment with more than three electrodes for impedance measurement.

FIG. 8 shows a schematic block diagram of a measuring assembly for determining the distribution of the magnetic gradient force including a schematic cross section of a probe body according to one embodiment with a plurality of diamagnetic particles in the probe suspension.

FIG. 9 shows a schematic perspective view of a measuring assembly for determining the distribution of the magnetic gradient force according to one embodiment with a camera as optical measuring device.

FIG. 10 shows a schematic overview of a measuring assembly for determining the distribution of the magnetic gradient force according to one embodiment with switchable electrodes for impedance measurement and a probe suspension with a single-phase liquid.

FIG. 11 shows a schematic overview of a measuring assembly for determining the distribution of the magnetic gradient force according to another embodiment with switchable electrodes for impedance measurement and a probe suspension with a two-phase liquid.

FIG. 12 shows a schematic diagram, explaining the effects of the embodiments.

### DETAILED DESCRIPTION

In the following detailed description, reference is made to the accompanying drawings. The accompanying drawings form part of the description and show, for illustrative purposes, specific embodiments which can be used for producing the invention. Directional terminology such as “top”, “bottom”, “front”, “rear”, “anterior”, “posterior”, etc., is used with reference to the orientation of the figure(s) described. Since components of the embodiments can be positioned in a number of different orientations, the directional terminology is for explanatory purposes only and is not to be understood to be restrictive in any way. In addition to the embodiments sketched, there are additional embodiments. Structural or logical changes can be made to the embodiments depicted in the figures and/or described in the following text, without deviating from the subject matter claimed. Features of the embodiments described can be combined with one another, unless expressly or inherently indicated otherwise.

One aspect of the present disclosure relates to a measuring assembly for determining the magnetic gradient force in a magnetic field, in particular, the spatial distribution of the magnetic term of the component of the magnetic gradient force that is antiparallel to the gravitational force in an inhomogeneous magnetic field.

The measuring assembly comprises a probe body in which a hollow space is formed, and a probe suspension in the hollow space.

The probe body is a workpiece made of a diamagnetic or weakly paramagnetic working material, for example, a sphere, a tube or an essentially cuboidal plate. The working material may be an inorganic material, for example, silicon oxide, quartz, glass, soda-lime glass, sapphire, ceramic, or an organic material, e.g., a polyimide, polytetrafluoroethylene (PTFE), or polymethyl methacrylate (acrylic glass).

The hollow space can be an open trench on a front side of the probe body, a closed chamber in the probe body, or part of a system of interconnected chambers and channels in the probe body. The hollow space, for example, has a circular or polygonal base area and a height along a hollow space axis that is perpendicular to the base area. The hollow space can be rotationally symmetrical to the hollow space axis, for example, cubic, cylindrical or spherical. The size of a cross-sectional area of the hollow space that is parallel to the base area can be largely independent of the distance to the base area of the hollow space. The cross-sectional area can be up to 1 cm² e.g., within a range from 0.1 mm² to 1 cm², from 0.1 mm² to 5 mm², or from 0.1 mm² to 1 mm². The height of a cubic or cylindrical hollow space that is perpendicular to the base area can be up to 5 cm.

The probe suspension can fill the hollow space completely or partially. The probe suspension contains a liquid and at least one diamagnetic particle.

In particular, the probe suspension contains a liquid with at least one paramagnetic phase with a magnetic susceptibility χ. For example, the one phase of the probe suspension may contain or be a paramagnetic salt in an aqueous solution, several paramagnetic salts in an aqueous solution, an ionic liquid, an organic solvent and/or a silicon-based oil.

The diamagnetic particle(s) can be substantially homogeneous particles of exactly one material or may consist of two or more different materials, wherein the material(s) is/are not soluble in the liquid or is/are soluble only to a non-significant extent.

In addition, the measuring assembly includes a measuring device which is configured to determine a distance d of the diamagnetic particle(s) relative to a horizontal reference plane on the probe body.

The reference plane of the probe body can be defined by a local property of the probe body that can be easily and reliably detected and determined locally, e.g., optically, electrically and/or mechanically. For example, the lower or the upper main surface of a cuboid probe body represents the reference plane. Alternatively, a marking, e.g., a colored line or an indentation on an outer surface of the probe body can define the position of the reference plane. Alternatively, the lower edge or the upper edge of the hollow space or the position of the liquid surface in the hollow space can define the position of the reference plane.

The measuring device detects the position of the particle(s) in the hollow space relative to the reference plane and, for example, can use optical and/or electrical properties of the particle(s) and/or liquid for this purpose.

On a vertical axis that is parallel to the direction of the gravitational force, the position of a particle in the probe suspension relative to the reference plane initially results from the equilibrium condition for weight force and buoyancy force.

If the probe body is located in an inhomogeneous magnetic field with a gradient of the magnetic flux density ∇B, then the magnetic gradient force fₘ additionally acts on each diamagnetic particle in the probe suspension. If the gradient of the magnetic flux density ∇B has a component that is parallel to the direction of the gravitational force, then, in a liquid with a paramagnetic phase with a magnetic susceptibility χ and a density ρ_{f} for a diamagnetic particle with a density ρₚ, there is exactly one location at a distance d from the reference plane along the vertical axis at which the equilibrium condition is fulfilled. The distance d of a diamagnetic particle from the reference plane is therefore a measure of the magnetic gradient force fₘ acting on the diamagnetic particle according to equation (1):

$${f}_{m} = χ \cdot \frac{\partial {B}^{2}}{2 {μ}_{0} \partial z} \qquad ( 1 )$$

The local distribution for the distance d therefore qualitatively reflects the local distribution of the magnetic gradient force.

After all, the measuring assembly comprises a probe positioning unit which is configured to determine a geometric location of the hollow space and/or the at least one particle relative to a stationary reference location outside the probe body, wherein the reference location is invariable relative to the inhomogeneous magnetic field, and the geometric location can be indicated by position data related to the reference location.

For example, the probe positioning unit can include a positioning unit that moves the probe body along one, two or three Cartesian or cylindrical spatial axes. For this purpose, the positioning unit can have a movable object table or object arm to which the probe body can be attached.

The position data of the respective geometric location of the hollow space or the dielectric particle(s) for which the distance d is determined can result indirectly from the respective spatial coordinates of the probe body approached by the positioning unit. Alternatively or additionally, the probe positioning unit can comprise a localization device that determines the location of the probe body using measurement technology. For example, the probe positioning unit can comprise an optical measuring device that tracks the probe body optically and determines the spatial coordinates in an optical way. Alternatively or additionally, the probe positioning unit can comprise a radio wave transmitter attached to the probe body, two or more antennas for the radio waves emitted by the radio wave transmitter, and a receiving device that determines the location of the probe body based on the signals received by the antennas.

To determine the distribution of the magnetic gradient force in a magnetic field or the magnetic contribution, the probe body is introduced into the magnetic field and oriented in such a manner that the reference plane of the probe body is perpendicular to the direction of the gravitational force and the hollow space axis of the hollow space is oriented vertical, i.e., parallel to the direction of the gravitational force.

For different positions of the probe body in the magnetic field, the distance d between the diamagnetic particle(s) and the reference plane is determined by the measuring device respectively and allocated to the respective position data. The distances d determined by the measuring device for different positions represent the distribution of the component of the magnetic force gradient fₘ that is antiparallel to the gravitational force in the magnetic field being examined. The small spatial extension of the diamagnetic particle(s) makes it possible to determine the distribution of the magnetic gradient force fₘ or the contribution [symbol] ·∇ [symbol] with high spatial resolution.

A data set can thereby be generated that allocates a distance value d to a plurality of positions respectively.

Conventional probes for characterizing magnetic fields, e.g., Hall probes, average magnetic field strength or flux density over a not insignificant volume. In addition, the amount of the magnetic gradient force can only be derived indirectly from the measured values for magnetic field strength or flux density for a predetermined location, for which an at least locally homogeneous term [symbol] ·∇ [symbol] is assumed in most cases. The local resolution for the magnetic gradient force that can be achieved with Hall probes is therefore in the order of magnitude of the characteristic length of the Hall probe, which is typically 5 mm to 10 mm.

Compared to an indirect determination of the magnetic term of the gradient force by means of a probe based on the Hall effect, the measuring assembly according to the present embodiments enables a significantly finer spatial resolution and the determination of the magnetic gradient force even in such magnetic fields for which no locally linearly stratified contribution [symbol] ·∇ [symbol] can be assumed, i.e., in magnetic fields with a locally strongly inhomogeneous magnetic field change, as they occur, in particular, but not only, in the field of microfluidics and in the biological context. The measuring assembly enables direct measurement of the contribution [symbol] ·∇ [symbol] and thus a magnetic field characterization with high accuracy and high spatial resolution.

More precise knowledge of the course of the magnetic term of the gradient force in an inhomogeneous magnetic field, for example, improves the accuracy of examinations that can lead to a better understanding of effects that occur during the magnetic separation of cells and rare earth particles. In installations for separating rare earth ions and biological material by means of magnetic levitation, the magnetic fields and assemblies required for this can be calibrated more precisely.

According to one embodiment, the measuring assembly comprises an evaluation unit which is configured to determine, from the distance d determined by the measuring device, a physical variable which describes the magnetic gradient force acting on the diamagnetic particle(s).

In particular, the evaluation unit can be configured, taking into account the balance of forces between the buoyancy force f_{b} and the magnetic gradient force fₙ at the distance d from the reference plane, as well as known parameters or measured values, to determine the magnetic contribution

$$\frac{\partial {B}^{2}}{2 {μ}_{0} \partial z} ( \vec{B} \cdot ∇ \vec{B} )$$

of the magnetic gradient force fₘ and/or the magnetic gradient force fₘ based on equations (2) to (4).

The parameters or measured values known comprise the distance d determined by the measuring assembly, the distance do of the particle(s) from the reference plane outside a magnetic field with a component that is parallel to the gravitational force, the susceptibility χ of the paramagnetic liquid, and the difference in density Δρ=ρₚ−ρ_{f} between the liquid and the diamagnetic particle:

$${f}_{m} = {f}_{b} \qquad ( 2 )$$

$${f}_{m} = χ \cdot \frac{\partial {B}^{2}}{2 {μ}_{0} \partial z} \qquad ( 3 )$$

$${f}_{b} = Δρ \cdot g \qquad ( 4 )$$

Such a finely measured magnetic field can be used to determine the magnetic susceptibility χ of a paramagnetic liquid by using the above equations under the condition that the distribution of the contribution [symbol] ·∇ [symbol] is known.

An additional aspect of the present disclosure relates to a measuring assembly for determining the magnetic gradient force in a magnetic field, in particular, for determining the magnetic term of the component of the magnetic gradient force that is antiparallel to the gravitational force in an inhomogeneous magnetic field.

The measuring assembly comprises a probe body in which a hollow space is formed, and a probe suspension in the hollow space.

The probe body is a workpiece made of a diamagnetic or weakly paramagnetic working material, for example, a sphere, a tube or an essentially cuboidal plate. The working material may be an inorganic material, for example, silicon oxide, quartz, glass, soda-lime glass, sapphire, ceramic, or an organic material, e.g., a polyimide, polytetrafluoroethylene (PTFE), or polymethyl methacrylate (acrylic glass).

The hollow space can be an open trench on a front side of the probe body, a closed chamber in the probe body, or part of a system of interconnected chambers and channels in the probe body. The hollow space, for example, has a circular or polygonal base area and a height along a hollow space axis that is perpendicular to the base area. The hollow space can be rotationally symmetrical to the hollow space axis, for example, cylindrical or spherical.

The size of a cross-sectional area of the hollow space that is parallel to the base area can be largely independent of the distance to the base area of the hollow space or change with the distance to the base area. The cross-sectional area can be up to 1 cm² e.g., within a range from 0.1 mm² to 1 cm², from 0.1 mm² to 5 mm², or from 0.1 mm² to 1 mm². The height of the hollow space that is perpendicular to the base area can be at least 10 nm and up to 5 cm, e.g., up to 5 mm, up to 5 μm, or up to 500 nm. For example, the cross-sectional area is at least 100 nm², and the height is at least 10 nm.

The probe suspension can fill the hollow space completely or partially. The probe suspension contains a liquid and at least one diamagnetic particle.

In particular, the probe suspension contains a liquid with at least one paramagnetic phase with a previously known magnetic susceptibility χ and a density ρf. For example, the one phase of the probe suspension may contain or be a paramagnetic salt in an aqueous solution, several paramagnetic salts in an aqueous solution, an ionic liquid, an organic solvent and/or a silicon-based oil.

The diamagnetic particle(s) can be substantially homogeneous particles of exactly one material or may consist of two or more different materials, wherein the material(s) is/are not soluble in the liquid or is/are soluble only to a non-significant extent.

The density ρp of the at least one diamagnetic particle and the density of ρf the paramagnetic liquid or at least the difference in density Δρ=ρp−ρf between the density ρf of the paramagnetic liquid and the density pp of the at least one diamagnetic particle are known in advance.

In addition, the measuring assembly includes a measuring device which is configured to determine a distance d of the diamagnetic particle(s) relative to a horizontal reference plane on the probe body.

The reference plane of the probe body can be defined by a local property of the probe body that can be easily and reliably detected and determined locally, e.g., optically, electrically and/or mechanically. For example, the lower or the upper main surface of a cuboid probe body represents the reference plane. Alternatively, a marking, e.g., a colored line or an indentation on an outer surface of the probe body can define the position of the reference plane. Alternatively, the lower edge or the upper edge of the hollow space or the position of the liquid surface in the hollow space can define the position of the reference plane.

The measuring device detects the position of the particle(s) in the hollow space relative to the reference plane and, for example, can use optical and/or electrical properties of the particle(s) and/or liquid for this purpose.

As already described above, the distance d of a diamagnetic particle from the reference plane is a measure of the magnetic gradient force fₘ acting on the diamagnetic particle according to equation (1) above.

The displacement Δd=d−d0 caused by the magnetic field results from the distance d and a distance d0 of the particle(s) from the reference plane outside a magnetic field with a component that is parallel to the gravitational force.

In addition, the measuring assembly includes an evaluation unit that is configured to determine, from the distance d determined by the measuring device, a physical variable which describes the magnetic gradient force acting on the diamagnetic particle(s).

In particular, the evaluation unit can be configured, taking into account the balance of forces between the buoyancy force f_{b} and the magnetic gradient force fₘ at a distance d from the reference plane, to determine from the distance d determined by the measuring assembly or from the displacement dv, from the previously known susceptibility χ of the paramagnetic liquid, and from the difference in density Δρ=ρp−ρf between the paramagnetic liquid and the diamagnetic particle, the magnetic contribution

$$\frac{\partial {B}^{2}}{2 {μ}_{0} \partial z} or \vec{B} \cdot ∇ \vec{B}$$

of the magnetic gradient force fₘ and/or the magnetic gradient force fₘ based on equations (2) to (4) above.

Such a finely measured magnetic field can be used to determine the magnetic susceptibility χ of another paramagnetic liquid of an initially unknown susceptibility χ by applying the above equations under the condition that the difference in density Δρ between the paramagnetic liquid and the diamagnetic particle is known, and that, in particular, the term [symbol] ·∇ [symbol] is known at the location of measurement, in particular, at the location of the at least one diamagnetic particle.

To determine a magnetic gradient force at a position in an unknown magnetic field, a probe body is positioned in the magnetic field as described above. In particular, the probe body has a hollow space, wherein the hollow space contains a liquid with at least one paramagnetic phase and at least one diamagnetic particle. In the magnetic field, a displacement of the at least one diamagnetic particle along an axis that is parallel to the direction of the gravitational force is determined relative to an initial position of the diamagnetic particle in the hollow space. From the displacement, the previously known susceptibility χ of the at least one paramagnetic phase and the previously known difference in density between the density ρp of the at least one diamagnetic particle and the density ρf of the at least one paramagnetic phase, a physical variable is determined which describes a magnetic gradient force on fm acting the diamagnetic particle(s), e.g., the gradient force fm itself and/or the magnetic contribution B·∇B.

According to one embodiment, the measuring assembly can include a probe positioning unit which is configured to determine a geometric location of the hollow space and/or the at least one diamagnetic particle relative to a stationary reference location outside the probe body, wherein the reference location is invariable relative to the inhomogeneous magnetic field, and the geometric location can be indicated by position data related to the reference location.

For example, the probe positioning unit can include a positioning unit that moves the probe body along one, two or three Cartesian or cylindrical spatial axes. For this purpose, the positioning unit can have a movable object table or object arm to which the probe body can be attached.

The position data of the respective geometric location of the hollow space or the dielectric particle(s) for which the distance d is determined can result indirectly from the respective spatial coordinates of the probe body approached by the positioning unit. Alternatively or additionally, the probe positioning unit can comprise a localization device that determines the location of the probe body using measurement technology. For example, the probe positioning unit can comprise an optical measuring device that tracks the probe body optically and determines the spatial coordinates in an optical way. Alternatively or additionally, the probe positioning unit can comprise a radio wave transmitter attached to the probe body, two or more antennas for the radio waves emitted by the radio wave transmitter, and a receiving device that determines the location of the probe body based on the signals received by the antennas.

According to one embodiment, each of the evaluation units described above can be further configured to allocate position data each determined by the probe positioning unit at different geometric locations to distances d determined by the measuring device.

In particular, the evaluation unit can be configured to create a data set from distances d determined by the measuring device for a plurality of locations in a magnetic field and from the position data output by the probe positioning unit, wherein the data set allocates the distance d determined for the respective position data to a plurality of different position data.

For example, the evaluation unit continuously receives position data from the probe positioning unit and initiates a measurement of the distance d by the measuring device at coordinates approached by the probe positioning unit. Alternatively, the evaluation unit can continuously receive values for the distance d from the measuring device and initiate the query of the coordinates at the time of measurement of the distance d from the probe positioning unit.

Alternatively, the evaluation unit continuously receives both values for the distance d from the measuring device and position data from the probe positioning unit and allocates such position data to each distance d that is received at the same time or in the same time window as the distance d.

Alternatively, the evaluation unit continuously receives values combined with a first time stamp for the distance d from the measuring device and position data combined with a second time stamp from the probe positioning unit and allocates such position data to the distances d the time stamps of which largely or completely match.

Alternatively, the evaluation unit initiates a measurement of the distance d by the measuring device and/or its transmission to the evaluation unit after position data has been transmitted to the evaluation unit by the probe positioning unit. Alternatively, the evaluation unit simultaneously initiates a measurement of the distance d by the measuring device and the determination of the position data by the probe positioning unit.

The data sets compiled by the evaluation unit each allocate a distance d determined by the measuring device to a plurality of position data respectively. In particular, the evaluation unit can be configured to create a data set from the distances d determined by the measuring device for a plurality of locations in a magnetic field, from a known susceptibility χ of the paramagnetic liquid and from the difference in density Δρ=ρₚ−ρ_{f} between the liquid and the diamagnetic particle, which allocates a value for the magnetic term of the gradient field and/or the amount of the magnetic gradient force fₘ to a plurality of position data respectively. Such a data set inherently contains a spatial map of the distribution of the magnetic term of the gradient force and/or the magnetic gradient force fₘ.

According to one embodiment, the probe suspension can contain exactly one diamagnetic particle with a previously known density ρₚ. The diamagnetic particle can be approximately round.

The position of a single diamagnetic particle can be determined relatively easily in a reliable and precise manner. In addition, a single diamagnetic particle can be easily adapted to an application in terms of shape, size and material composition.

According to one embodiment, the probe suspension may contain a plurality of diamagnetic particles of a similar type with a previously known density ρₚ.

The diamagnetic particles can be approximately round and approximately the same size, wherein the diameters can be at least 5 nm. The number of particles can be selected as a function of their diameter in such a manner that the particles can be arranged straight into a single layer in a horizontal cross section of the hollow space, i.e., without any vertical overlapping of particles.

The position of a layer with relatively small particles can be detected with precision. The diamagnetic particles can be relatively small, wherein the spatial resolution of the measurement can be improved with decreasing spatial extension of the particles. Further conclusions about the distribution of the magnetic gradient force can be drawn from the relative position of the particles to one another along the vertical axis of the hollow space.

The diamagnetic particle(s) include(s) a material or a combination of materials that is not soluble to a significant extent in any of the phases of the liquid.

According to one embodiment, the diamagnetic particle(s) can include or consist of dielectric materials. The dielectric material enables an electrical measurement of the distance d, e.g., by means of an impedance measurement.

For example, the diamagnetic particles consist predominantly or, apart from production-related impurities, completely of an inorganic dielectric material such as silicon oxide, quartz, glass, sapphire, or of ceramic, an organic dielectric material, e.g., polyimide, PTFE, or polymethyl methacrylate.

According to one embodiment, the diamagnetic particle(s) can include an organic and an inorganic dielectric material.

For example, a first sub-area of the diamagnetic particle has or consists of a first dielectric material, and a second sub-area of the diamagnetic particle has or consists of a second dielectric material. The first sub-area and the second sub-area can be approximately the same size.

In particular, the diamagnetic particle can be an amphiphilic particle or the diamagnetic particles can be amphiphilic particles, each having a hydrophobic first sub-area and a hydrophilic second sub-area.

Amphiphilic diamagnetic particles can be combined with liquids with an aqueous phase and with an organic phase, wherein the hydrophobic sub-area of an amphiphilic particle is immersed into the organic phase and the hydrophilic sub-area into the aqueous phase.

For example, the amphiphilic diamagnetic particle has or the amphiphilic diamagnetic particles each have a first sub-area made of PTFE or PMMA (polymethyl methacrylate) and a second sub-area made of hydrophilic silicon dioxide (SiO₂). The two sub-areas can be approximately the same size, wherein an amphiphilic diamagnetic particle can consist of 50% PTFE or PMMA and 50% SiO₂. Amphiphilic diamagnetic particles can be solid particles or hollow bodies, e.g., hollow spheres or hollow prisms, such as hollow cubes, wherein the mean density of an amphiphilic particle can lie between the densities of the organic phase and the aqueous phase. In particular, the amphiphilic particle(s) can be located outside a magnetic field at the interface between the organic phase and the aqueous phase.

A relative displacement volume of an amphiphilic diamagnetic particle at the interface between an aqueous phase and an organic phase is directly proportional to the magnetic contribution [symbol] ·∇ [symbol] . This means that the measuring range for the magnetic gradient force can be significantly increased compared to a comparable probe with a single-phase liquid, given comparable dimensions for the hollow space and particle, i.e., given a comparable spatial resolution. A single probe can cover a comparatively large measuring range for the magnetic gradient force.

According to one embodiment, the liquid contains two or more phases that are immiscible with one another, wherein the diamagnetic particle(s) is/are dispersible in the at least two immiscible phases.

Each of the phases can contain or consist of a paramagnetic salt in an aqueous solution, several paramagnetic salts in an aqueous solution, an ionic liquid, an organic oil, a silicon-based oil and/or an alcohol, wherein at least one of the phases exhibits paramagnetic properties. For example, one of the two phases is a chloride solution of a rare earth, e.g., a dysprosium (III) chloride solution (DyCl₃). Another phase can be a silicon-based oil, for example, a silicone oil.

Furthermore, one of the two phases or both phases can be selected from the following group of organic solutions: carbon tetrachloride, chlorobenzene, cyclohexane, heptane, hexane, pentane, toluene and triethyl amine.

At least two of the phases can have different densities. For example, the density of the phase of higher density is at least 110% of the density of the phase of lower density. Alternatively or additionally, at least two of the phases can have different magnetic susceptibilities. For example, one of the phases does not exhibit paramagnetic properties, or the magnetic susceptibility of the phase of higher magnetic susceptibility is at least 110% of the magnetic susceptibility of the phase of lower magnetic susceptibility.

The difference between the magnetic susceptibilities influences the magnetic gradient force. The difference between the densities influences buoyancy. As the displacement of the diamagnetic particles depends on buoyancy and magnetic gradient force and therefore on both differences, the measuring accuracy and measuring range of the measuring assembly can be adjusted by selecting the appropriate phases.

The diamagnetic particle(s) is/are dispersible in all phases of the liquid and can be trapped along the boundary layer between two phases.

Since the buoyancy force depends on the difference in density between particle and liquid, and the magnetic gradient force depends on the magnetic susceptibility, the composition of the probe suspension determines the measuring range of a probe, which comprises the probe body and the probe suspension introduced into the hollow space. The measuring range of the probe can be extended by selecting the appropriate phases of a multi-phase liquid. To map a magnetic field with a high gradient, fewer passes with probes with different measuring ranges are required. For many practical applications, a single pass with exactly one probe can be sufficient.

A density of a first one of the immiscible phases can be at least 110% of a density of a second one of the immiscible phases.

According to one embodiment, the measuring device can include a radiation source and a radiation sensor. The radiation source is configured to emit measurement radiation. The probe body and the radiation sensor are configured in such a manner that the radiation sensor detects part of the measuring radiation emitted by the radiation source passing through the hollow space and/or part of the measuring radiation reflected in the hollow space along a hollow space axis of the hollow space that is perpendicular to the reference plane in a space-resolved manner.

The measuring radiation can comprise any reasonably useful type of particle radiation, e.g., neutron radiation, or electromagnetic radiation, e.g., broadband radiation in the wavelength range of visible light, ultraviolet radiation, infrared radiation or and/or X-ray radiation, or narrowband radiation, e.g., laser radiation. The measuring device can include additional optical elements for guiding the measuring radiation, e.g., one or more mirrors, lenses, beam splitters and/or apertures.

Depending on the liquid and the material of the diamagnetic particles, the measuring radiation is selected in such a manner that the liquid is largely transparent and the diamagnetic particle(s) is/are absorbent and/or reflective to a higher degree than the liquid.

The radiation source can be stationary in relation to the magnetic field, wherein the exit point of the measuring radiation can be stationary in relation to the magnetic field or stationary in relation to the probe body. For example, a movably arranged optical waveguide directs the measuring radiation from a radiation source that is stationary in relation to the magnetic field to an entry surface on the probe body. Alternatively, the radiation be source can attached to the probe body. The radiation source, for example, can feature a point-shaped light source or a linear light source that is aligned parallel to the hollow space axis.

Similarly, the radiation sensor can be stationary in relation to the magnetic field, wherein the point of entry of the measuring radiation into the radiation be sensor can stationary in relation to the magnetic field or stationary in relation to the probe body. For example, a movably arranged optical waveguide directs the measuring radiation from an exit surface on the probe body to an entry surface of the radiation sensor. Alternatively, the radiation sensor can be attached to the probe body. For example, the radiation sensor comprises one or more multi-pixel image sensors that are arranged parallel to the hollow space axis. The distribution of radiation detected by the radiation sensor can be used to infer the distance d of a dielectric particle from the reference plane.

According to one embodiment, the measuring device can include an impedance measuring device, wherein the impedance measuring device is configured to determine a local electrical impedance of the probe suspension along a hollow space axis that is perpendicular to the reference plane in a space-resolved manner.

For example, the impedance measuring device works with a periodic signal as an excitation signal, wherein the impedance measuring device determines the complex impedance between two electrodes on sides the different of hollow space. Alternatively or additionally, the impedance measuring device can include a capacitance measuring device, wherein the capacitance measuring device is configured to determine the electrical capacitance along an axis that is perpendicular to the reference plane in a space-resolved manner. Alternatively or additionally, the impedance measuring device can include a resistance measuring device, wherein the resistance measuring device is configured to determine the electrical resistance along an axis that is perpendicular to the reference plane in a space-resolved manner.

According to one embodiment, the impedance measuring device can include at least one first electrode on a first side of the hollow space and at least two second electrodes on a second side of the hollow space, wherein the first side and the second side are opposite one another in relation to the hollow space axis that is vertical relative to the reference plane.

Due to the different conductivities and/or different dielectric properties of a liquid and a particle, the impedances between the first electrode on one hand and the second electrodes on the other hand change as a function of the vertical position of the diamagnetic particle(s), wherein exactly one distance d can be clearly allocated to each pair of values for the impedances between the first electrode and the one second electrode and between the first electrode and the other second electrode.

Such a function, for example, can be determined specifically for each measuring assembly in a calibration step that allocates impedance values for the impedance between the first electrode and the one second electrode and/or between the first electrode and the other second electrode to each distance d.

The further away the diamagnetic particle is from the electrodes on the vertical axis, the smaller the difference between two impedances measured at the same distance from one another. The impedance measuring device can therefore include two or more first electrodes and/or more than two second electrodes. On at least one side, one electrode can be arranged close to the base area and another electrode can be arranged close to the upper end of the hollow space. For example, three or more electrodes are arranged at approximately equal distances on the inside of the hollow space along a line that is parallel to the hollow space axis.

Another aspect of the present disclosure relates to another method for determining a distribution of a magnetic gradient force in a magnetic field. The method comprises moving a probe body within a magnetic field. The probe body has a hollow space. There is a liquid in the hollow space that contains at least one paramagnetic phase and at least one diamagnetic particle. At different positions of the probe body in the magnetic field, a displacement of the at least one diamagnetic particle along an axis that is parallel to the direction of the gravitational force is determined relative to an initial position of the diamagnetic particle in the hollow space. The initial position corresponds to the position of the at least one diamagnetic particle in the magnetic field-free space.

The method can comprise compiling a data set, wherein the data set allocates the displacement of the at least one diamagnetic particle from the initial position determined at the respective position in the magnetic field to a plurality of positions in the magnetic field.

The data set can be output and/or further processed at a data interface for further evaluation and/or visualization.

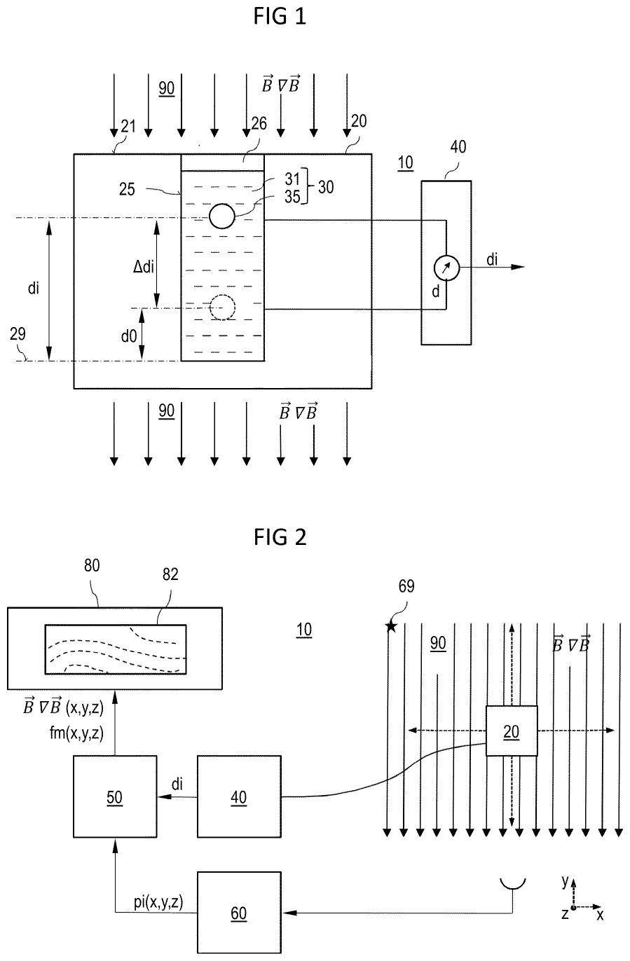

FIG. 1 shows a simplified block diagram of a measuring assembly 10 for determining the magnetic gradient force.

The measuring assembly 10 includes a probe body 20 and a measuring device 40. The probe body 20 is depicted in cross section. The probe body 20 is a cuboid workpiece. A perforated trench extends vertically into the probe body 20 from a first surface 21 on the front side of the probe body 20.

The perforated trench contains a probe suspension 30. A cover 26 can close the perforated trench after the probe suspension 30 has been introduced into it. The covered part of the perforated trench forms a sealed hollow space 25, which is completely filled by the probe suspension 30.

The probe suspension 30 contains a liquid 31 and a diamagnetic particle 35, wherein the liquid 31 in this example contains exactly one paramagnetic phase.

The measuring device 40 measures the distance d between the dielectric particle 35 and a reference plane 29, which is defined by a lower edge of the hollow space 25 in the example sketched.

Outside a magnetic field, i.e., in a magnetic field-free space, a distance do of the diamagnetic particle 35 from the reference plane 29 results from the equilibrium of forces between the buoyancy force acting on the diamagnetic particle 35 and the gravitational force.

To measure the distribution of the magnetic gradient force in a magnetic field 90 with a component that is parallel to the gravitational force, the probe body 20 is moved within the magnetic field 90. The probe body 20 remains oriented in such a manner that the reference plane 29 is perpendicular to the gravitational force and a hollow space axis of the hollow space 25 is parallel to the gravitational force.

In an inhomogeneous magnetic field 90, the additionally acting magnetic gradient force causes, at the position pᵢ, a displacement Δdᵢ of the dielectric particle 25 from the initial position at do along the vertical axis.

The respective displacement Δdᵢ is a measure of the amount of a component the gradient of magnetic force that acts antiparallel to the gravitational force at the respective particle position pᵢ. The measuring device 40 measures the distance dᵢ=Δdᵢ+d0 of the diamagnetic particle 35 from the reference plane 29 for different positions pᵢ in the magnetic field 90 respectively.

FIG. 2 schematically shows an example of a controlled movement of the probe body 20 along orthogonal linear spatial axes x, y, z in a magnetic field 90.

A probe positioning unit 60 determines the position data pᵢ (x,y,z) for the location of the sensor body 20 in the magnetic field 90 at the time of measurement of a distance dᵢ. The probe positioning unit 60 can actively specify the position data pᵢ(x,y,z) or passively determine such position data. For example, the probe positioning unit 60 has a controllable, movable object arm to which the probe body 20 is attached. The probe positioning unit 60 approaches the position data pᵢ(x,y,z) according to a predetermined rule. Alternatively or additionally, the probe positioning unit 60 includes a localization device that determines the position data pᵢ(x,y,z) of the probe body 20 at the time of measurement of the distance dᵢ using measurement technology.

The position data pᵢ(x,y,z) is related to a stationary reference point 69 the position of which is invariable relative to the magnetic field. The position of the dielectric particle 35 at the time of the respective measurement can also be determined from the position data pᵢ(x,y,z) and the distances dᵢ.

An evaluation unit 50 is connected by data technology to the measuring device 40 and the probe positioning unit 50 and receives the respective position data pᵢ(x,y,z) and the measured distance dᵢ for each measurement.

The evaluation unit 50 allocates the corresponding position data pᵢ(x,y,z) to each measured distance dᵢ. The evaluation unit 50 determines the magnetic gradient force fₘ and/or the magnetic gradient ∇B for each measuring point from the distance d determined for the measuring point and outputs the result at a data interface. The output result directly or indirectly describes the distribution of the magnetic gradient force fₘ(x,y,z) or [symbol] ·∇ [symbol] (x,y,z) in the magnetic field 90.

A graphical user interface 80 receives the data output by the evaluation unit 50 and graphically depicts the distribution of the magnetic gradient force in the magnetic field 90 on a display 82.

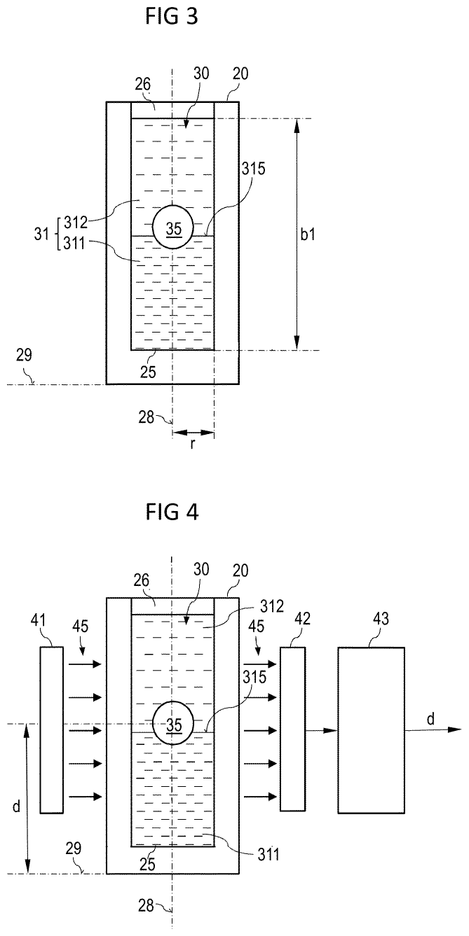

In FIG. 3, the probe body 20 has a chamber-like hollow space 25 with a round cross-sectional area with the radius r1. The hollow space axis 28 of the hollow space 25 runs parallel to the direction of the gravitational force. A vertical extension b1 of the hollow space 25 is up to 5 cm. A cover 26 closes the hollow space 25 after the introduction of a probe suspension 30 into it.

The probe suspension contains a liquid with a denser or heavier first phase 311 and a less dense or lighter second phase 312 compared thereto. The first phase 311 and the second phase 312 are immiscible and form a horizontal interface (phase boundary) 315. At least one of the phases 311, 312 is paramagnetic. The other phase 312, 311 is paramagnetic or non-paramagnetic, e.g., diamagnetic.

A diamagnetic particle 35 floats in the liquid 31 and touches or breaks through the interface 315. The diamagnetic particle 35 can be approximately spherical.

For example, the diamagnetic particle 35 is an amphiphilic particle that has a hydrophobic sub-area and a hydrophilic sub-area. The two sub-areas can be connected to one another along a flat interface. The two sub-areas can be approximately the same size, wherein the amphiphilic diamagnetic particle can consist of approximately 50% PTFE or PMMA and the remainder of SiO₂. One of the phases 311, 312 can be an organic phase, the other phase 312, 311 an aqueous phase.

A mean density of the amphiphilic diamagnetic particle 35 can lie between the densities of the two phases 311, 312. The amphiphilic diamagnetic particle 35 aligns itself with the plane interface between the two sub-areas horizontally and parallel to the phase boundary 315. Outside of a magnetic field, the amphiphilic diamagnetic particle 35 floats at the phase boundary or in the area of the phase boundary 315, or breaks through the phase boundary 315.

FIG. 4 shows a measuring device 40 with a linear radiation source 41 on a first side of the sensor body 20, a linear radiation sensor 42 on a side of the sensor body 20 that is opposite the radiation source 41, and an evaluation device 43. The longitudinal axes of the radiation source 41 and the radiation sensor 42 are parallel to the hollow space axis 28 of the hollow space 25. The radiation source 41 emits measuring radiation, e.g., broadband light or laser radiation, in the direction of the hollow space 25. The radiation sensor 42 can include an image line sensor with pixels arranged in a line or a sensor with two-dimensionally arranged pixels and receives part of the measuring radiation 45 passing through the hollow space 25.

The liquid, which, in the example shown, contains two phases 311, 312, and the dielectric particle 35 reflect and/or absorb the measuring radiation 45 emitted by the radiation source 41 to different degrees. The dielectric particle 35 casts a shadow on the radiation sensor 42.

The evaluation device 43 receives image information output by the radiation sensor 42 and uses the received image to determine the position of the diamagnetic particle 35 and, in particular, the mean distance d from the reference surface 29.

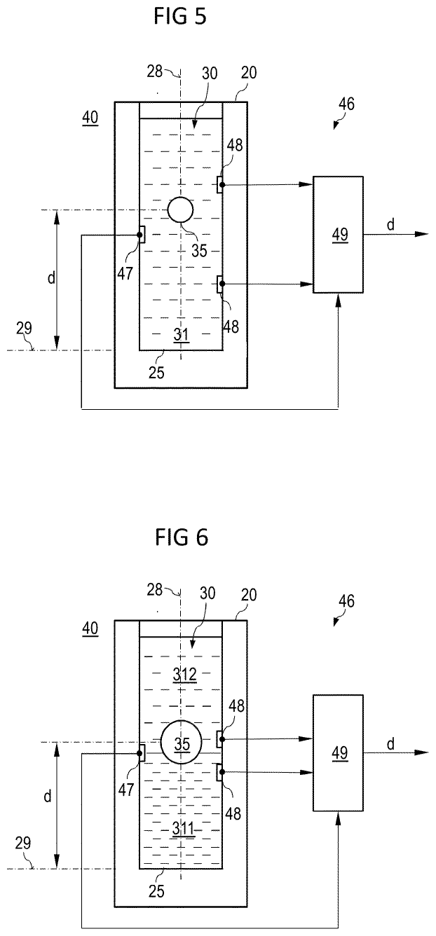

FIG. 5 and FIG. 6 show measuring devices 40 for a spatially resolved impedance measurement of the probe suspension 30. Each measuring device 40 has an impedance measuring device 46. The impedance measuring device 46 includes at least one first electrode 47 on a first side of the hollow space 25 and at least two second electrodes 48 on a second side of the hollow space 25, wherein the first side and the second side are opposite one another in relation to the longitudinal axis 28 of the hollow space 25 that is vertical to the reference plane 29.

A first electrode 47 and a second electrode 48 each form a pair of electrodes respectively. In the exemplary embodiment shown, the first electrode 47 and the upper second electrode 48 form the first pair of electrodes. The first electrode 47 and the lower second electrode 48 form the second pair of electrodes.

A signal evaluation unit 49 generates one or more excitation signals, which are applied to the pairs of electrodes, and determines the influence of the probe suspension 30 on the generated measuring signals. The position of the dielectric particle 35 relative to the second electrodes 48 influences the signal response and, in particular, a difference between the signal responses of the first pair of electrodes and the second pair of electrodes.

In FIG. 5, the liquid 31 of the probe suspension 30 contains exactly one paramagnetic phase. The diamagnetic particle 35 floats in an area between the lower edge and the upper edge of the hollow space 25 as a function of the amount of the effective magnetic gradient force.

In FIG. 6, the probe e suspension 30 contains exactly two immiscible liquid phases 311, 312. The diamagnetic particle 35 floats in the area of the interface 315 and immerses to a lesser extent or to a greater extent into the first liquid phase 311 as function of the amount of the effective magnetic gradient force.

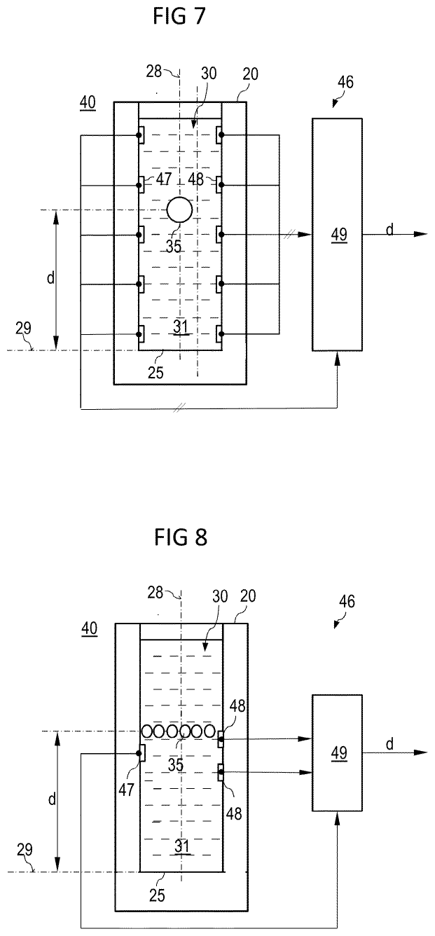

In FIG. 7, several first electrodes 47 are arranged along a first vertical line on the first side of the hollow space 25, and several second electrodes 48 are arranged along a second vertical line on the second side of the hollow space 25.

FIG. 8 refers to a probe suspension 30 with several diamagnetic particles 35. The diamagnetic particles 35 are approximately round and approximately the same size. The number of the diamagnetic particles 35 is selected in such a manner that the diamagnetic particles 35 are arranged still straight into a single layer in a horizontal cross section of the hollow space 25, i.e., without any vertical overlapping.

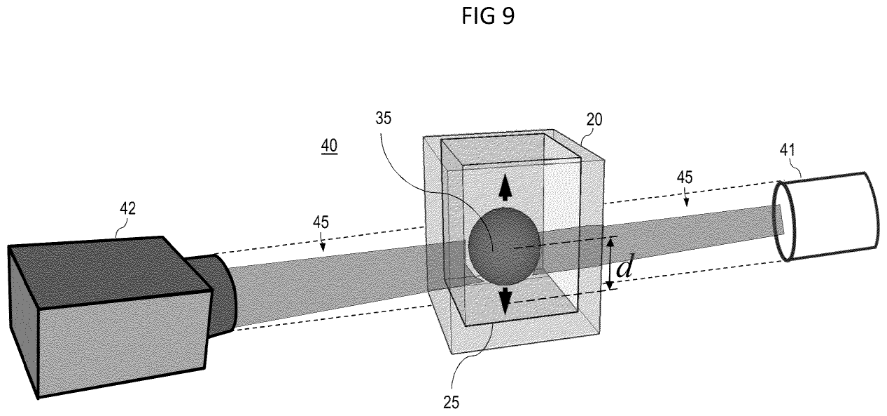

FIG. 9 shows another example of a measuring assembly 40, in which the hollow space 25 is arranged in the beam path of a measuring radiation 45 between a radiation source 41 and a radiation sensor 42. The radiation source 41 comprises an LED lamp. The radiation sensor 42 is a camera.

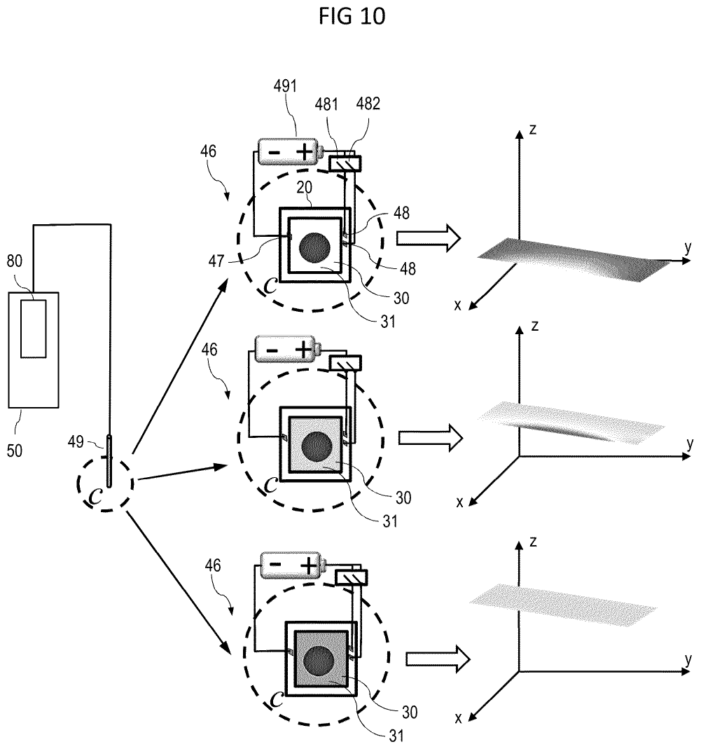

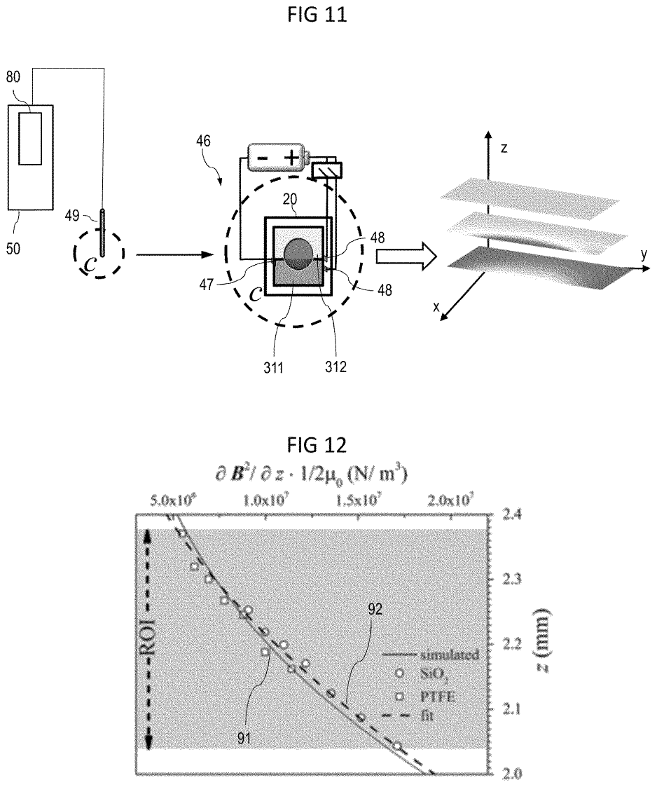

FIG. 10 and FIG. 11 show impedance measuring devices 46, wherein optionally a first pair of electrodes 47, 48 or a second pair of electrodes 47, 48 can be switched to a signal source 491 of a signal evaluation unit 49 via switches 481, 482. The signal evaluation unit 49 is connected by data technology to an evaluation unit 50. The evaluation unit 50 determines the distribution of the magnetic gradient force and depicts it graphically on a graphical user interface 80.

In FIG. 10, different probe suspensions 30 with different single-phase, paramagnetic liquids 31 are provided for different measuring ranges of the magnetic gradient force.

Several probes with different measuring ranges are required to determine the distribution of very different magnetic gradient forces.

In FIG. 11, a single probe suspension 30 with a two-phase liquid 311, 312 enables a wide measuring range.

FIG. 12 shows the results of a validation experiment by means of a measuring assembly according to FIG. 2, with a probe with a plurality of diamagnetic particles of a similar type according to FIG. 8 and with an optical measuring device according to FIG. 9. The probe has a cylindrical hollow space with a diameter of approximately 4 mm or a cubic hollow space with a square base area with an edge length of approximately 4 mm and with a vertical extension of 5 mm. The hollow space was successively filled with several probe suspensions, each containing a DyCl₃ solution in different concentrations and a particle cloud several with approximately spherical diamagnetic particles. A mean diameter of the diamagnetic particles is approximately 20 μm to 45 μm.

The probe was used to determine the distribution of the contribution

$$\frac{\partial {B}^{2}}{2 {μ}_{0} \partial z}$$

of a magnetic field along a measured distance, along which the contribution

$$\frac{\partial {B}^{2}}{2 {μ}_{0} \partial z}$$

increases over a distance of approximately 0.4 mm from approximately 5×10⁶ N/m³ to approximately 2×10⁷ N/m³.

The diagram shows the measured contribution

$$\frac{\partial {B}^{2}}{2 {μ}_{0} \partial z}$$

as a function of the measuring point over the measured distance. In the diagram, the circles indicate the result for probes with diamagnetic particles made of silicon dioxide with a density of 2500 kg/m³, and the squares indicate the results for probes with diamagnetic particles made of PTFE with a density of 2100 kg/m³. The dashed line 92 indicates the approximation curve obtained from the measuring results, which approximates well to the continuous line 91 of the simulation result.

1-15. (canceled)

16. A measuring assembly for determining a distribution of a magnetic gradient force, the measuring assembly comprising:
a probe body in which a hollow space is formed;
a probe suspension in the hollow space, wherein the probe suspension contains a liquid and at least one diamagnetic particle;
a measuring device configured to determine a distance of the at least one diamagnetic particle relative to a reference plane on the probe body; and
a probe positioning unit configured to determine a geometric location of the hollow space and/or the at least one diamagnetic particle relative to a stationary reference location outside the probe body.

17. The measuring assembly of claim 16, further comprising:
an evaluation unit configured to determine, from the distance determined by the measuring device, a physical variable which describes a magnetic gradient force acting on the at least one diamagnetic particle.

18. The measuring assembly of claim 17, wherein the evaluation unit is further configured to allocate distances determined by the measuring device at different geometric locations to position data determined by the probe positioning unit.

19. The measuring assembly of claim 16, wherein the probe suspension contains exactly one diamagnetic particle with a previously known density.

20. The measuring assembly of claim 16, wherein the probe suspension contains a plurality of diamagnetic particles of a similar type with a previously known density.

21. The measuring assembly of claim 16, wherein the at least one diamagnetic particle includes an organic and an inorganic dielectric material.

22. The measuring assembly of claim 16, wherein the liquid contains at least two immiscible phases, and wherein the at least one diamagnetic particle is dispersible in the at least two immiscible phases.

22. The measuring assembly of claim 16, wherein the measuring device includes a radiation source and a radiation sensor, wherein the radiation source is configured to emit a measuring radiation, and wherein the radiation sensor and the probe body are configured in such a manner that the radiation sensor detects part of the measuring radiation passing through the hollow space and/or part of the measuring radiation reflected in the hollow space along an axis that is perpendicular to the reference plane in a space-resolved manner.

23. The measuring assembly of claim 16, wherein the measuring device includes an impedance measuring device configured to determine an electrical impedance of the probe suspension along an axis that is perpendicular to the reference plane in a space-resolved manner.

24. The measuring assembly of claim 23, wherein the impedance measuring device includes at least one first electrode on a first side of the hollow space and at least two second electrodes on a second side of the hollow space, and wherein the first side and the second side are opposite one another in relation to a hollow space axis of the hollow space.

25. A measuring assembly for determining a magnetic gradient force, the measuring assembly comprising:
a probe body in which a hollow space is formed;
a probe suspension in the hollow space, wherein the probe suspension contains a liquid and at least one diamagnetic particle;
a measuring device configured to determine a distance of the at least one diamagnetic particle relative to a reference plane on the probe body; and
an evaluation unit configured to determine, from the distance determined by the measuring device, a physical variable which describes a magnetic gradient force acting on the at least one diamagnetic particle.

26. The measuring assembly of claim 25, further comprising:
a probe positioning unit configured to determine a geometric location of the hollow space and/or the at least one diamagnetic particle relative to a stationary reference location outside the probe body.

27. The measuring assembly of claim 25, wherein the evaluation unit is further configured to allocate distances determined by the measuring device at different geometric locations to position data determined by the probe positioning unit.

28. The measuring assembly of claim 25, wherein the probe suspension contains exactly one diamagnetic particle with a previously known density.

29. The measuring assembly of claim 25, wherein the probe suspension contains a plurality of diamagnetic particles of a similar type with a previously known density.

30. The measuring assembly of claim 25, wherein the at least one diamagnetic particle includes an organic and an inorganic dielectric material.

31. The measuring assembly of claim 25, wherein the liquid contains at least two immiscible phases, and wherein the at least one diamagnetic particle is dispersible in the at least two immiscible phases.

32. The measuring assembly of claim 25, wherein the measuring device includes a radiation source and a radiation sensor, wherein the radiation source is configured to emit a measuring radiation, and wherein the radiation sensor and the probe body are configured in such a manner that the radiation sensor detects part of the measuring radiation passing through the hollow space and/or part of the measuring radiation reflected in the hollow space along an axis that is perpendicular to the reference plane in a space-resolved manner.

33. The measuring assembly of claim 25, wherein the measuring device includes an impedance measuring device configured to determine an electrical impedance of the probe suspension along an axis that is perpendicular to the reference plane in a space-resolved manner.

34. The measuring assembly of claim 33, wherein the impedance measuring device includes at least one first electrode on a first side of the hollow space and at least two second electrodes on a second side of the hollow space, and wherein the first side and the second side are opposite one another in relation to a hollow space axis of the hollow space.

35. A method for determining a distribution of a magnetic gradient force in a magnetic field using a measuring assembly that includes a probe body in which a hollow space is formed, a probe suspension in the hollow space and containing a liquid and at least one diamagnetic particle, and a measuring device, the method comprising:
introducing the probe body into a magnetic field, wherein the probe body is oriented in such a manner that the reference plane is perpendicular to the direction of the gravitational force; and
determining a distance between the at least one diamagnetic particle and a reference plane on the probe body using the measuring device for different positions of the probe body in the magnetic field relative to a stationary reference location outside the probe body.

36. A method for determining a distribution of a magnetic gradient force in a magnetic field, the method comprising:
moving a probe body within a magnetic field, wherein the probe body has a hollow space and wherein the hollow space contains a liquid with at least one paramagnetic phase and at least one diamagnetic particle; and
determining a displacement of the at least one diamagnetic particle along an axis that is parallel to the direction of the gravitational force relative to an initial position of the at least one diamagnetic particle in the hollow space at different positions of the probe body in the magnetic field.

37. A method for determining a magnetic gradient force in a magnetic field, the method comprising:
positioning a probe body in the magnetic field, wherein the probe body has a hollow space and wherein the hollow space contains a liquid with at least one paramagnetic phase and at least one diamagnetic particle;
determining a displacement of the at least one diamagnetic particle along an axis that is parallel to the direction of the gravitational force relative to an initial position of the at least one diamagnetic particle in the hollow space; and
determining, based on the displacement, a susceptibility of the at least one paramagnetic phase, and a difference in density between a density of the at least one diamagnetic particle and a density of the at least one paramagnetic phase, a physical variable which describes a magnetic gradient force on the at least one diamagnetic particle.
